(19) United States
(12) Patent Application Publication
(10) Pub. No.: US 2016/0219755 A1
(43) Pub. Date: Jul. 28, 2016

(54) THERMOELECTRIC-COOLING-CHIP-BASED HEAT-DISSPATING SYSTEM

(71) Applicant: TAI-SOL ELECTRONICS CO., LTD., TAIPEI CITY (TW)

(72) Inventors: Yaw-Huey LAI, JHONGHE CITY (TW); Yun-Yeu YEH, TAIPEI CITY (TW); Sheng-Chin CHAN, TAIPEI CITY (TW)

(21) Appl. No.: 14/728,640

(22) Filed: Jun. 2, 2015

(30) Foreign Application Priority Data
Jan. 23, 2015 (TW) 104102294

(51) Int. Cl. H05K 7/20

(52) U.S. Cl. CPC H05K 7/20154

(57) ABSTRACT

A thermoelectric-cooling-chip-based heat-dissipating system includes a partition board; a thermoelectric cooling chip having a hot side and a cold side located at two opposite sides of the partition board; a cool-air zone containing an air passage, a first fan, and a first heatsink set, wherein the first heatsink set is deposited on the cold side of the thermoelectric cooling chip, and the first fan and the first heatsink set are located in the air passage, so that the first fan blows air around the first heatsink set to move along the air passage; and a heat-dissipating zone containing a second fan and a second heatsink set, wherein the second fan blows air toward the second heatsink set, and the second heatsink set is deposited on the hot side of the thermoelectric cooling chip; wherein, the cool-air zone and the heat-dissipating zone are isolated from each other.

### BACKGROUND OF THE INVENTION

1. Technical Field

The present invention relates to heat dissipation, and more particularly to a heat dissipating system with a thermoelectric cooling chip.

2. Description of Related Art

Conventionally a heat dissipating system is used on electric devices that generate heat in use. For example, a projector has its light source generating considerable heat during projection, so it needs a heat-dissipating system that includes many vents formed on its housing and a fan contained in the housing for drawing external, cool air toward the light source, i.e. the heat source, to dissipate heat.

However, when the external air is drawn into the housing, dust and suspensions are introduced into the projector as well. Thus, accumulations of such dust and suspensions can over time bring adverse effects to internal components of the projector and degrade heat-dissipating effects, in turn shortening the service life of the relevant electronic elements.

### BRIEF SUMMARY OF THE INVENTION

The primary objective of the present invention is to provide a thermoelectric-cooling-chip-based heat-dissipating system that uses a thermoelectric cooling chip for heat dissipation without introducing external air, thereby preventing dust and suspensions from entering the system.

Hence, according to the present invention, a thermoelectric-cooling-chip-based heat-dissipating system comprises: a partition board; at least one thermoelectric cooling chip, being penetrated through the partition board in a way that a hot side and a cold side of the thermoelectric cooling chip are located at two opposite sides of the partition board; a cool-air zone, being located beside one said side of the partition board and containing an air passage, a first fan, and a first heatsink set, wherein the first heatsink set is deposited on the cold side of the thermoelectric cooling chip, and the first fan and the first heatsink set are located in the air passage, so that the first fan blows air around the first heatsink set to move along the air passage; and a heat-dissipating zone, being located beside the other side of the partition board and containing a second fan and a second heatsink set, wherein the second fan blows air toward the second heatsink set, and the second heatsink set is deposited on the hot side of the thermoelectric cooling chip.

Thereby, the present invention uses the thermoelectric cooling chip to guide heat to the heat-dissipating zone for effective heat dissipation, and thus eliminates the need of introducing external air into the cool-air zone, thereby preventing dust and suspensions entering the system and accumulating on electronic elements, and improving the service life of the electronic elements.

### BRIEF DESCRIPTION OF THE SEVERAL VIEWS OF THE DRAWINGS

FIG. 1 is a perspective view of a first preferred embodiment of the present invention.

FIG. 2 is a schematic drawing showing the internal configuration of the first preferred embodiment of the present invention.

FIG. 3 is another schematic drawing showing the internal configuration of the first preferred embodiment of the present invention from a different viewpoint.

FIG. 4 is a top view of the internal configuration of the first preferred embodiment of the present invention.

FIG. 5 is another schematic drawing showing the internal configuration of the first preferred embodiment of the present invention showing that an air-guiding plate is additionally provided.

FIG. 6 is a schematic drawing showing the internal configuration of a second preferred embodiment of the present invention.

FIG. 7 is a top view of the internal configuration of the second preferred embodiment of the present invention.

FIG. 8 is a schematic drawing showing the internal configuration of a third preferred embodiment of the present invention.

### DETAILED DESCRIPTION OF THE INVENTION

The invention as well as a preferred mode of use, further objectives and advantages thereof will be best understood by reference to the following detailed description of illustrative embodiments when read in conjunction with the accompanying drawings.

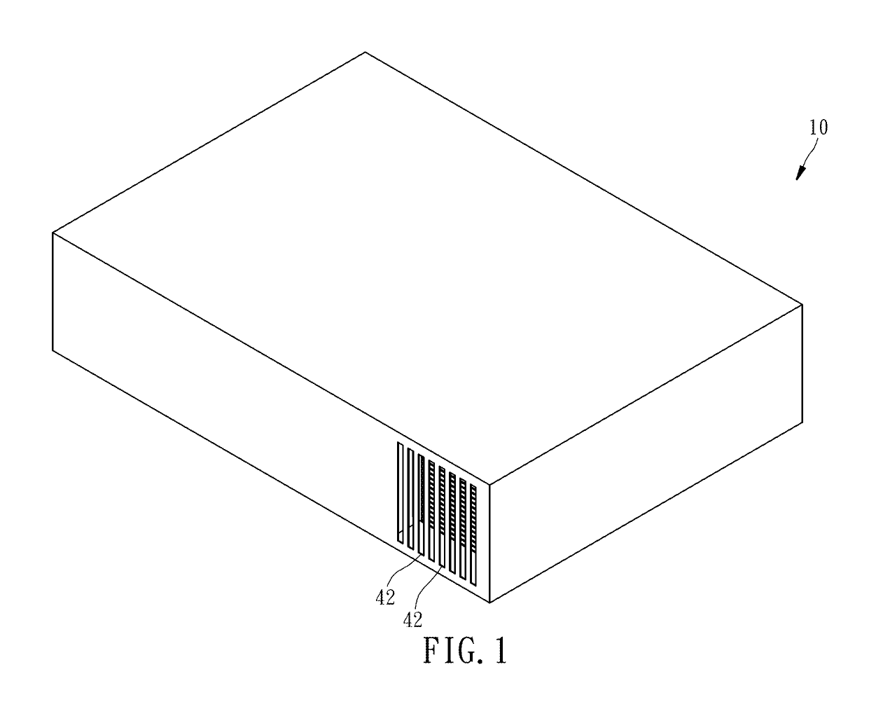

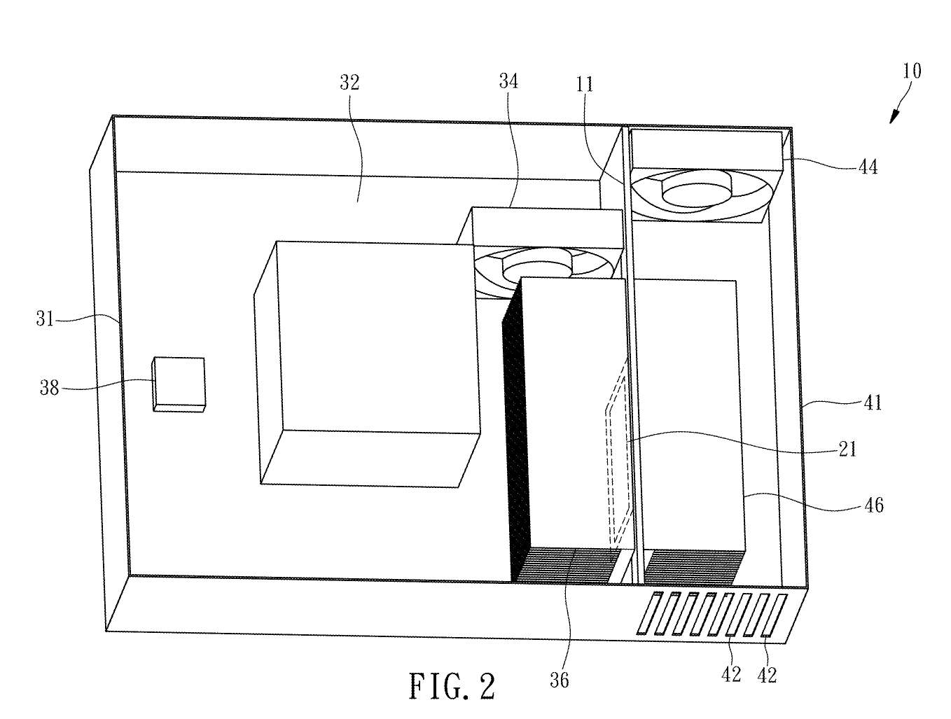

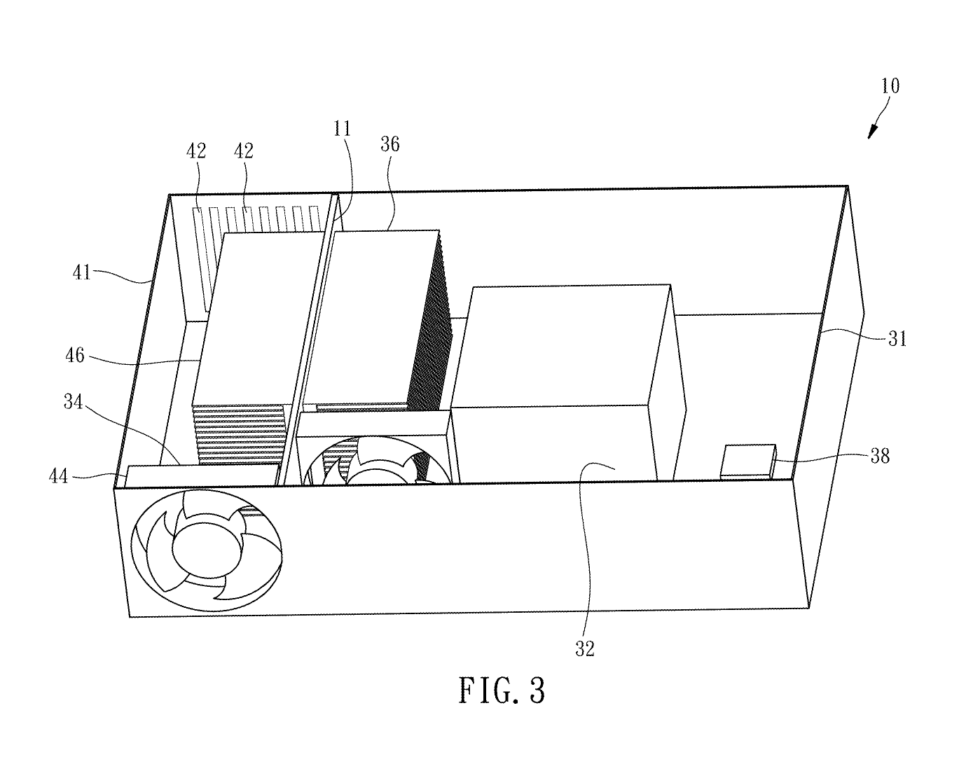

As shown in FIG. 1 through FIG. 4, according to a first preferred embodiment of the present invention, a thermoelectric-cooling-chip-based heat-dissipating system 10 primarily comprises a partition board 11, at least one thermoelectric cooling chip 21, a cool-air zone 31, and a heat-dissipating zone 41.

The number of at least one thermoelectric cooling chip 21 in the present embodiment is one. The thermoelectric cooling chip 21 is penetrated through the partition board 11 in a way that its hot side and cold side are located at two opposite sides of the partition board 11. In practical implementation, the number of at least one thermoelectric cooling chip 21 is not limited to one, and more said thermoelectric cooling chips 21 may be used.

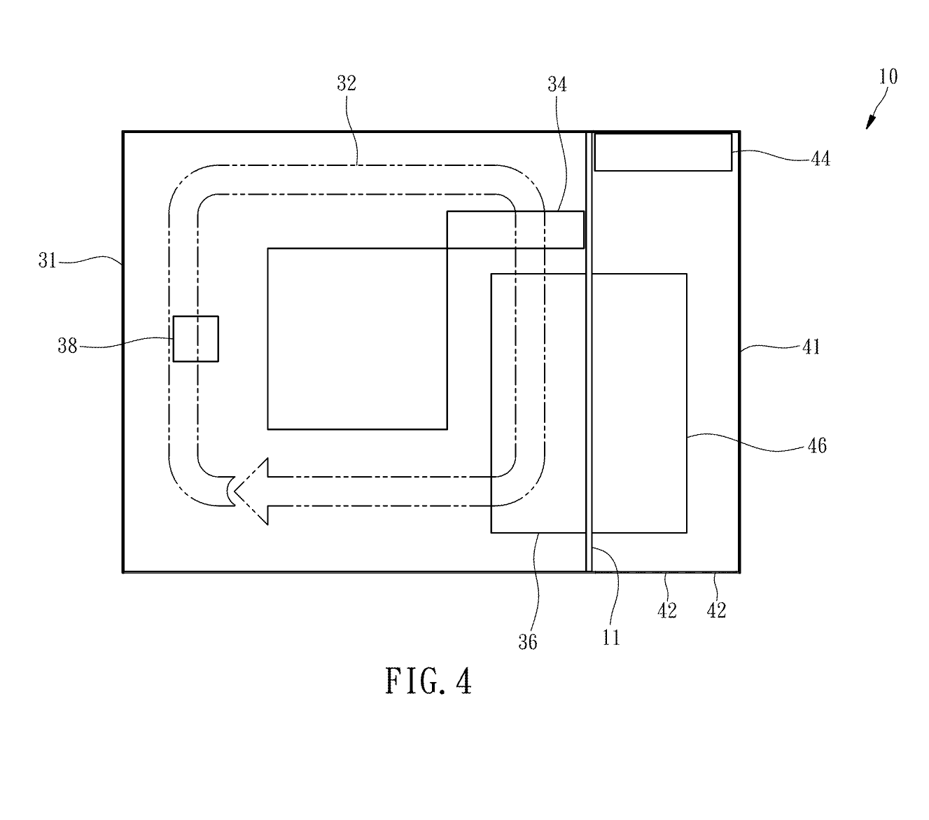

The cool-air zone 31 is located beside one of the two sides of the partition board 11. The cool-air zone 31 contains therein an air passage 32, a first fan 34, and a first heatsink set 36. The first heatsink set 36 is deposited on the cold side of the thermoelectric cooling chip 21. The first fan 34 and the first heatsink set 36 are located in the air passage 32. The first fan 34 blows air around the first heatsink set 36 to move along the air passage 32. The cool-air zone 31 may be either open or closed. In the present embodiment, the cool-air zone 31 is closed. In such a case, the air passage 32 can, as shown in FIG. 4, be realized directly by the pass way naturally defined by the internal space of the cool-air zone 31. However, where the cool-air zone 31 is laid open, the air passage has to be tubular, so as to prevent the air blown by the first fan 34 from escaping.

The heat-dissipating zone 41 is located at the other side of the partition board 11, and contains therein a second fan 44 and a second heatsink set 46. The second fan 44 blows air to the second heatsink set 46. The second heatsink set 46 is deposited on the hot side of the thermoelectric cooling chip 21. In the present embodiment, the heat-dissipating zone 41 is a chamber that is communicated with the exterior through a plurality of vents 42.

wherein, the cool-air zone 31 and the heat-dissipating zone 41 are isolated from each other.

With the configuration as described above, the first embodiment of the present invention works in the way as detailed below.

Since the first heatsink set 36 is deposited on the cold side of the thermoelectric cooling chip 21, the cooling effect generated at the cold side as a result of the operation of the thermoelectric cooling chip 21 can turn the air around the first heatsink set 36 into cool air by means of thermal conduction. The first fan 34 blows the cool air around the first heatsink set 36 to move along the air passage 32, so as to cool the air inside the air passage 32. The heat generated at the hot side during the operation of the thermoelectric cooling chip 21 can also be transferred to the second heatsink set 46 by means of thermal conduction. Then the second fan 44 blows the air in the heat-dissipating zone 41 toward the second heatsink set 46 to bring away the heat on the second heatsink set 46, thereby providing heat dissipation to the hot side. In terms of outcome, the foregoing operation transfers the heat in the cool-air zone 31 to the heat-dissipating zone 41 for heat dissipation.

In the first embodiment, the cool-air zone 31 further contains a heat source 38, and the air passage 32 forms circulation inside the cool-air zone 31. The heat source 38 is located in the air passage 32. The air blown into the air passage 32 passes by the heat source 38 and cools down the heat source 38 before circulating and returning to the first fan 34. Thereby, since the cool-air zone 31 is closed, the heat source 38 or other to-be-cooled devices inside the cool-air zone 31 can be cooled by the thermoelectric cooling chip 21 using the heat-dissipating zone 41 without introducing external air. This prevents dust and suspensions from entering the cool-air zone 31 and accumulating on the heat source 38 or other to-be-cooled devices, thereby improving heat dissipation and in turn the service life of the relevant elements.

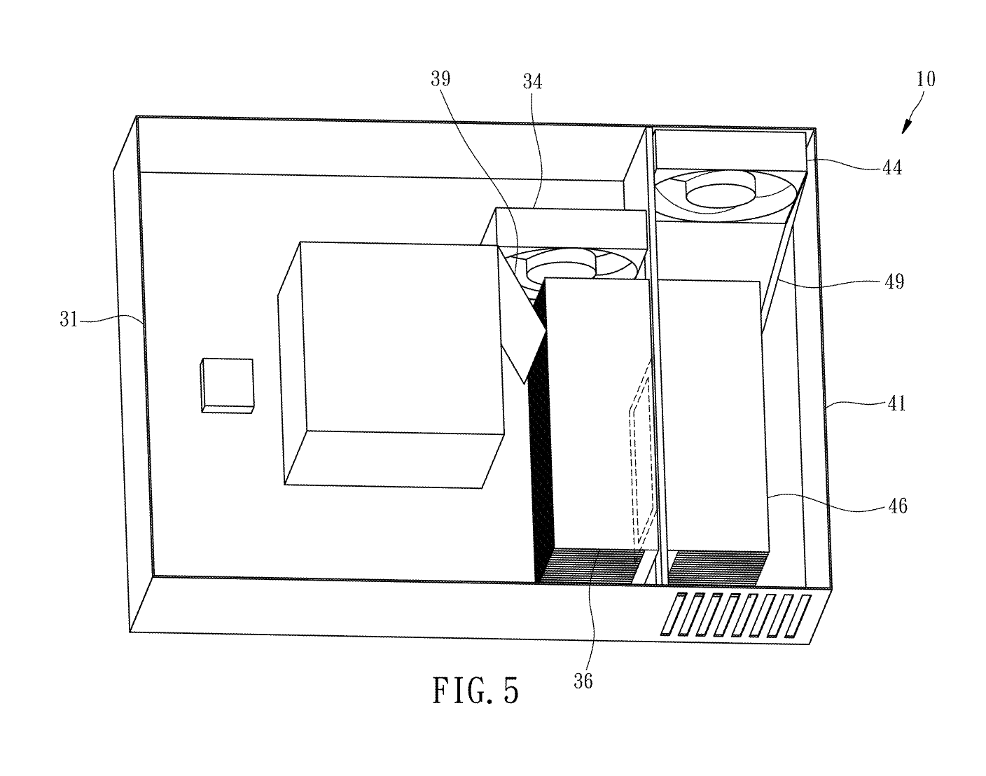

Additionally, as shown in FIG. 5, the cool-air zone 31 may further contain a first air-guiding plate 39 that is located beside the first fan 34 for guiding the air blown by the first fan 34 to the first heatsink set 36. The heat-dissipating zone 41 may also contain a second air-guiding plate 49 that is located beside the second fan 44 for guiding the air blown by the second fan 44 to the second heatsink set 46. Thereby, thermal conduction and heat dissipation can be further improved.

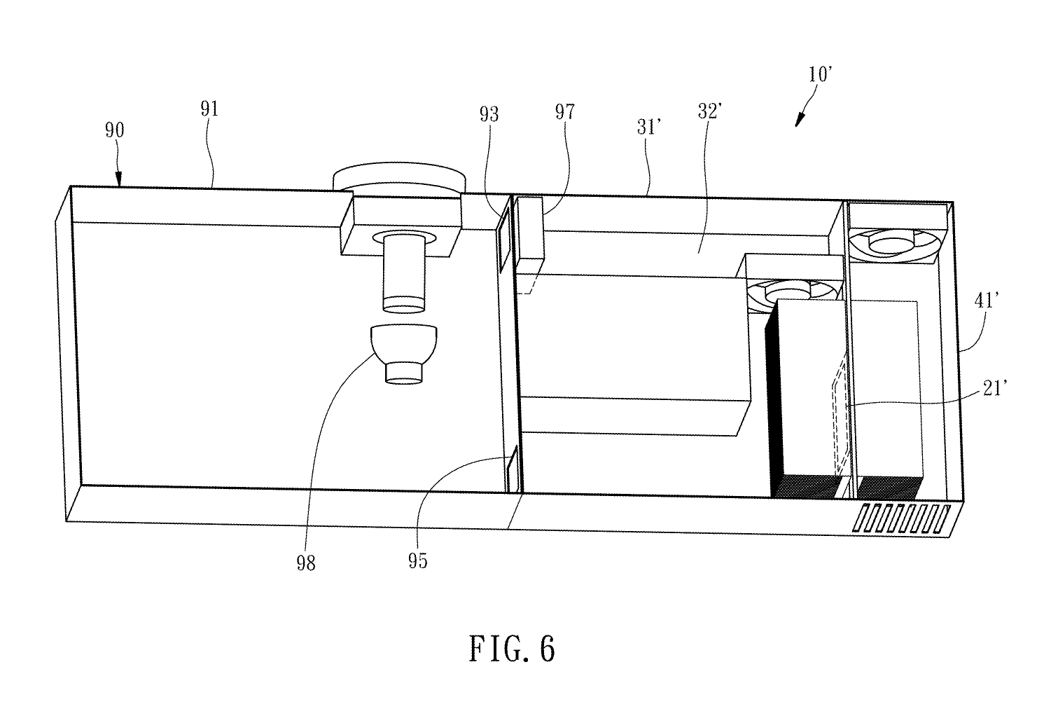

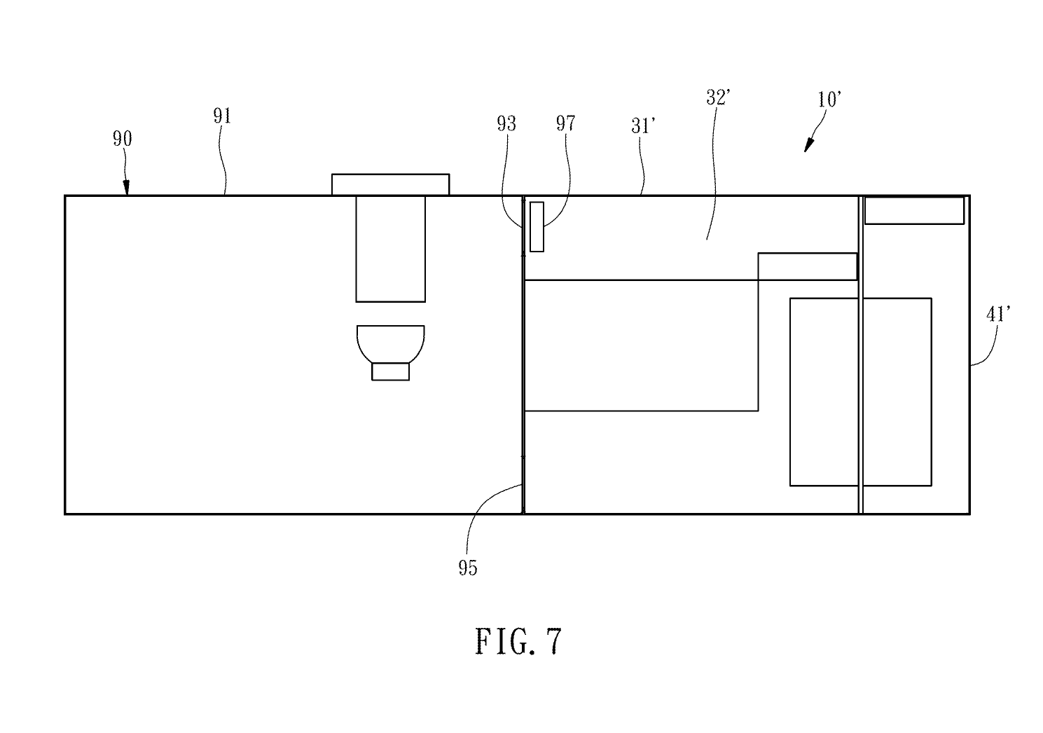

Referring to FIGS. 6 and 7, in a second preferred embodiment of the present invention, a thermoelectric-cooling-chip-based heat-dissipating system 10′ is generally similar to the previously discussed first embodiment, but has the following differences.

There is no heat source in the cool-air zone 31′.

In addition, the cool-air zone 31′ is a closed chamber connected to an external device 90 (such as a projector as shown). The external device 90 contains a heat-source room 91, and a heat source 98 is set in the heat-source room 91. The external device 90 has its surface formed with a first return port 93 and a second return port 95 that are in special communication with the air passage 32′ of the cool-air zone 31′. Therein, the air passage 32′ does not form circulation in the cool-air zone 31′. Instead, it has two ends thereof communicated with the first return port 93 and the second return port 95, respectively, thereby forming circulation with the interior of the heat-source room 91. A reflux fan 97 is deposited on the surface of the external device 90 and is located at the first return port 93 for blowing air inside the heat-source room 91 of the external device 90 to the air passage 32′ of the cool-air zone 31′. Air in the air passage 32′ thus is pushed and returns to the heat-source room 91 through the second return port 95.

Under the effect of the reflux fan 97, the cool air in the cool-air zone 31′ enters the heat-source room 91, thereby cooling the heat source 98 in the external device 90 (i.e. heat dissipation), and continuously circulates and enters the cool-air zone 31′. Then the heat is dissipated through the heat-dissipating zone 41′ in the same way as described in the first embodiment. Therefore, the heat-source room 91 of the external device 90 can also be closed and only in special communication with the cool-air zone 31′ through the first return port 93 and the second return port 95. Thereby, the thermoelectric cooling chip 21′ can effectively dissipate heat without introducing external air into the external device 90, so as to prevent dust and suspensions from entering the external device 90.

It is thus learned that based on the way the second embodiment works with the external device 90, the present invention can be applied to various existing electronic devices.

Since the other structural features and effects of the second embodiment are similar to those of the first embodiment, repetitive description is herein omitted.

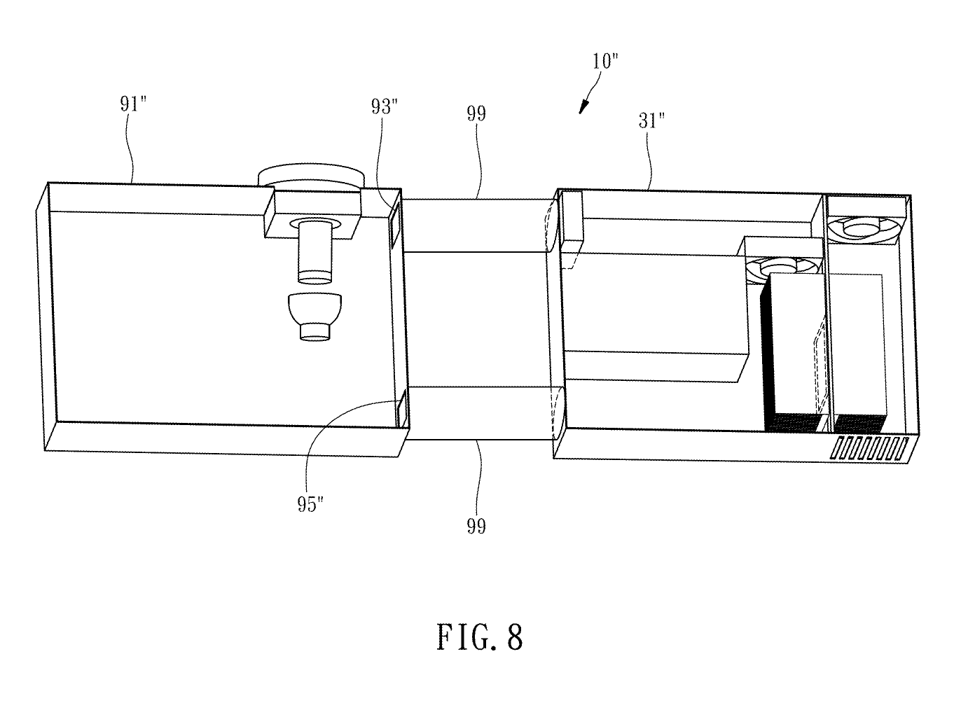

Referring to FIG. 8, in a third preferred embodiment of the present invention, a thermoelectric-cooling-chip-based heat-dissipating system 10″ is generally similar to the previously discussed second embodiment, but has the following difference.

The cool-air zone 31″ is communicated with the first return port 93″ and the second return port 95″ of the heat-source room 91″ through two tubes 99, respectively. Thereby, the cool-air zone 31″ has not to be next to the heat-source room 91″, and air can be transferred by way of the two tubes 99.

Since the other structural features and effects of the third embodiment are similar to those of the first embodiment, repetitive description is herein omitted.

What is claimed is:

1. A thermoelectric-cooling-chip-based heat-dissipating system, comprising:
a partition board;
at least one thermoelectric cooling chip, being penetrated through the partition board in a way that a hot side and a cold side of the thermoelectric cooling chip are located at two opposite sides of the partition board;
a cool-air zone, being located beside one said side of the partition board and containing an air passage, a first fan, and a first heatsink set, wherein the first heatsink set is deposited on the cold side of the thermoelectric cooling chip, and the first fan and the first heatsink set are located in the air passage, so that the first fan blows air around the first heatsink set to move along the air passage; and
a heat-dissipating zone, being located beside the other side of the partition board and containing a second fan and a second heatsink set, wherein the second fan blows air toward the second heatsink set, and the second heatsink set is deposited on the hot side of the thermoelectric cooling chip;
wherein, the cool-air zone and the heat-dissipating zone are isolated from each other.

2. The thermoelectric-cooling-chip-based heat-dissipating system of claim 1, wherein the heat-dissipating zone is open to and communicated with the exterior.

3. The thermoelectric-cooling-chip-based heat-dissipating system of claim 1, wherein the heat-dissipating zone is a chamber that is communicated with the exterior through a plurality of vents.

4. The thermoelectric-cooling-chip-based heat-dissipating system of claim 1, wherein the cool-air zone contains a heat source that is located in the air passage, and the air passage forms circulation inside the cool-air zone.

5. The thermoelectric-cooling-chip-based heat-dissipating system of claim 1, wherein the cool-air zone is a closed chamber connected to an external device that includes a heat-source room containing a heat source, and the external device has a surface that is formed with a first return port and a second return port that are in special communication with the cool-air zone, and is provided with a reflux fan located at the first return port for blowing air in the heat-source room of the external device toward the air passage of the cool-air zone, so that air in the air passage is pushed to return to the heat-source room through the second return port.

6. The thermoelectric-cooling-chip-based heat-dissipating system of claim 5, wherein the cool-air zone is communicated to the first return port and the second return port of the heat-source room through two tubes, respectively.

7. The thermoelectric-cooling-chip-based heat-dissipating system of claim 1, wherein the cool-air zone contains a first air-guiding plate located next to the first fan for guiding the air blown by the first fan toward the first heatsink set, and the heat-dissipating zone contains a second air-guiding plate located next to the second fan for guiding the air blown by the second fan toward the second heatsink set.
